(19) United States
(12) Patent Application Publication
(10) Pub. No.: US 2003/0161118 A1
(43) Pub. Date: Aug. 28, 2003

(54) Front panel serving as extraction lever for circuit sled mount

(75) Inventor: Eric T. Bovell, Branford, CT (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: Netezza Corporation, Framingham, MA

(21) Appl. No.: 10/090,116

(22) Filed: Feb. 28, 2002

(51) Int. Cl. H05K 5/00; H05K 5/04; H05K 5/06

(52) U.S. Cl. 361/759

(57) ABSTRACT

A front panel for a circuit sled module performs several functions. The panel serves as the front panel to the circuit sled module, the panel comprises one or more hooks for engaging a catch on the tray when in a closed position, and the panel serves as an extraction lever when in the open position for removing the circuit sled module from the tray.

### BACKGROUND OF THE INVENTION

The present invention relates generally to arrays of circuit board modules. An example of such an array is one that contains many circuit sled modules for hard disk drives (HDD) which are often used in large-scale database applications. In such an array, one or more trays are used to house a plurality of circuit board or sled modules. A typical module has a chassis to which a HDD is mounted, the HDD, a circuit board, and a front panel. The ends of such a circuit sled module typically contain mating connectors which mate with corresponding mating connectors at the end of the tray. A typical front panel is permanently affixed to the chassis and may contain holes through which screws can be inserted to screw the sled module to a portion of the tray in which it is housed. Removal of the sled module would require the removal of the screws and then pulling the module until it is free of the tray. Other arrangements do provide for removable sled modules that use a pair of levers to insert or extract the module from the rack. This arrangement typically requires that any front panel be an assembly that is separate from the circuit modules themselves.

### SUMMARY OF THE INVENTION

The present invention comprises a panel for a circuit sled module which operates to lock the sled module in place when it is in the tray and also serves as an extraction lever for removing the sled module from the tray. As the panel is rotated, it operates to provide the necessary forces to either engage or disengage the mating connectors between the circuit sled module and the tray it is being mounted on. The panel may have a front side, a top, a bottom, left and right side walls extending from the front, holes in the side walls toward the bottom of the panel, and at least one hook near the bottom of the panel. The holes are for receiving a rod or screw or rivet which connect the front panel to the circuit sled module and forming an axis about which the panel can rotate. The hook(s) are located near the bottom of the panel and engage a catch on a tray when the circuit sled module is properly mounted in the tray and the panel is in a closed position. The hooks can extend from a lower portion of the side wall or can be separate from the side wall themselves.

The panel may further comprise a screw or fastener or clipping mechanism for releasably locking the panel to the circuit sled module when the panel is in a closed position. In addition to providing a mounting base for the hooks for engaging a catch on the tray when the panel is in a closed position, the panel also serves as a lever for extracting the circuit sled module from the tray when the panel is an open position. The front panel may further comprise vents in the front of the panel to allow air flow between the circuit sled module and the outside environment. The panel may also comprise electrically conductive grounding tabs for grounding the panel to an adjacent panel or circuit sled module or the tray itself. The circuit sled module may comprise a hard disk drive.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 shows a circuit sled module having a front panel in the open position.

FIG. 2 shows a circuit sled module having a front panel in a closed position.

FIG. 3 shows a tray for housing multiple circuit sled modules.

FIG. 4 shows a closeup of two circuit sled modules housed within a tray.

FIG. 5 shows a closeup view of the hooks at the bottom of a front panel of a circuit sled module engaging the catch on the tray.

FIGS. 6A-6D show a sled insertion sequence.

FIGS. 7A-7D show a sled extraction sequence.

### DETAILED DESCRIPTION OF THE INVENTION

A description of preferred embodiments of the invention follows.

The present invention comprises a front panel for a circuit sled module which performs several functions. First, the panel serves as the front panel for the circuit sled module. Second, the panel has one or more hooks for engaging a catch on the tray for locking the circuit sled module in place when the panel is in a closed position. Third, when the panel is in an open position, it serves as an extraction lever for extracting the circuit sled module from the tray.

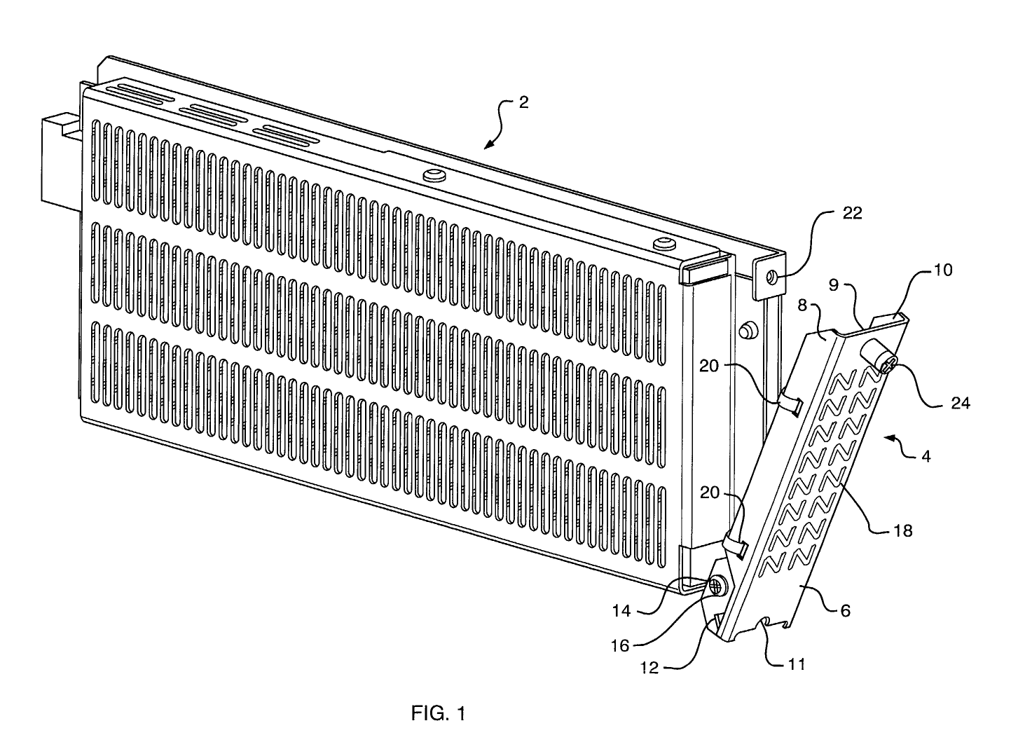

FIG. 1 shows a circuit sled module 2 having such a front panel 4. The panel has a front 6, a top 9, a bottom 11, a left side wall 8, and a right side wall 10. Towards the bottom of the panel there are one or more hooks 12 which will engage a catch on the tray when the circuit sled module is inserted into the tray and the panel is in a closed position. Also near the bottom portion of the panel are holes 16 for receiving a rod or screw or rivet 14 that is attached to the circuit sled module. In the embodiment depicted in FIG. 1, both the hole 16 and the hook 12 are shown on a separate side wall extension than the left side wall 8. In other embodiments, the left side wall 8 can extend further down the length of the panel and the hole 16 can be integrated in that left side wall 8. Similarly, the hook(s) 12 can also be either integrated with the side walls 8 and 10 or separate as shown in FIG. 1.

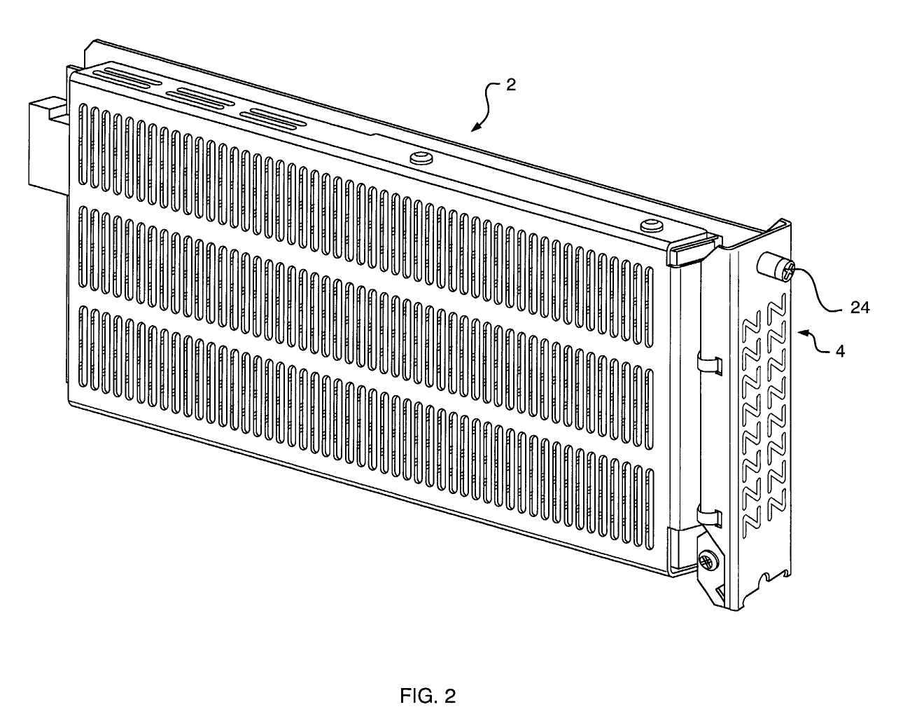

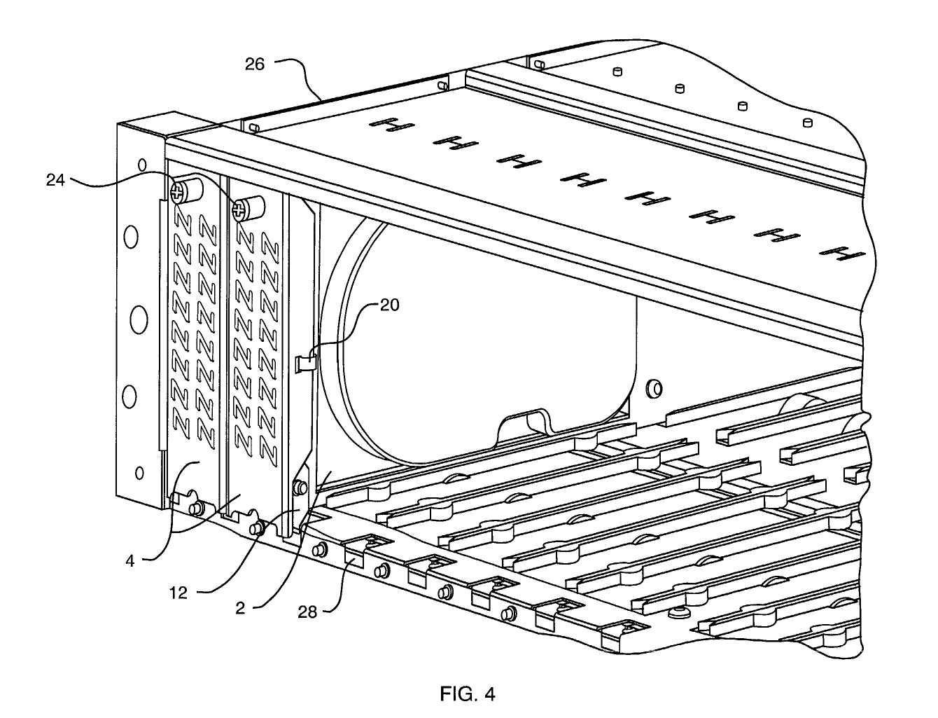

In a preferred embodiment, the panel contains some additional features. The panel may comprise vents 18 allowing air to flow into and out of the circuit sled module. The panel may also comprise grounding tabs 20 for electrically grounding the circuit sled module. The ground tabs 20 can be located on either or both side walls. In FIG. 1, two grounding tabs 20 are shown on the left sidewall and in FIG. 4, one grounding tab 20 is shown on the right sidewall. Lastly, the panel may contain a means for releasably locking the front panel to the circuit sled module. In FIG. 1, the fastener shown is the screw 24 which screws to the hole 22 in the circuit sled module, thereby locking the panel 4 to the sled module 2 when the circuit sled module is in a tray and in the locked position. A circuit sled module 2 with the panel 4 shown in a closed position is shown in FIG. 2.

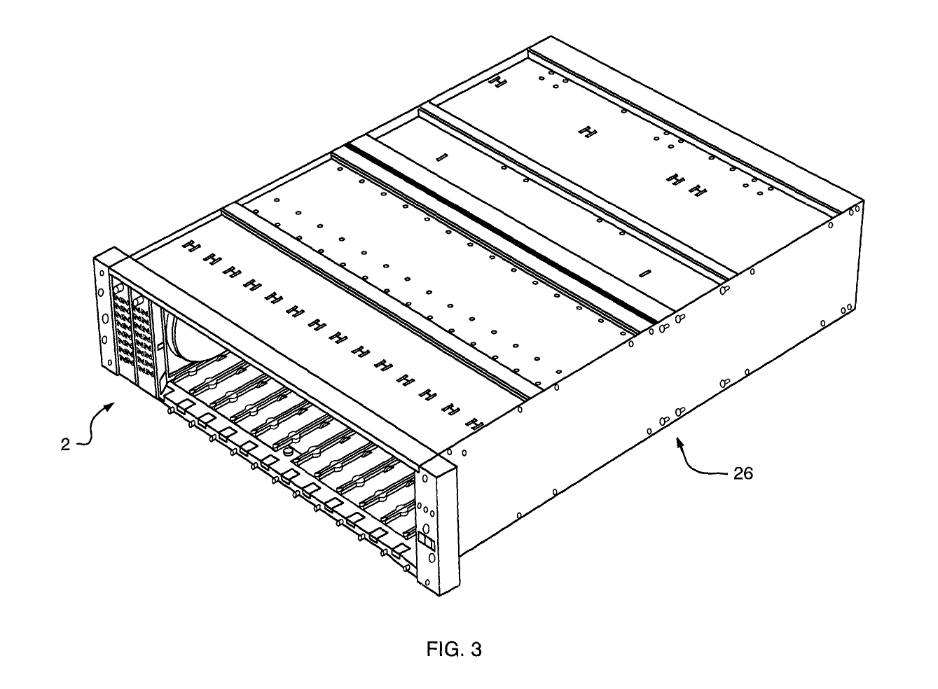

FIG. 3 shows a tray 26 for housing a plurality of circuit sled modules 2. In FIG. 3 two circuit sled modules are shown and the rest of the slots in the tray are empty.

FIG. 4 shows an enlarged section of the tray 26 which houses two circuit sled modules 2. In this drawing, the front panels 4 are shown in a closed position. In this position, the hooks 12 engage a catch 28 on the tray 26. When the panel 4 is in this closed position, and the screw 24 is screwed closed, the circuit sled module 2 is locked into the tray 26.

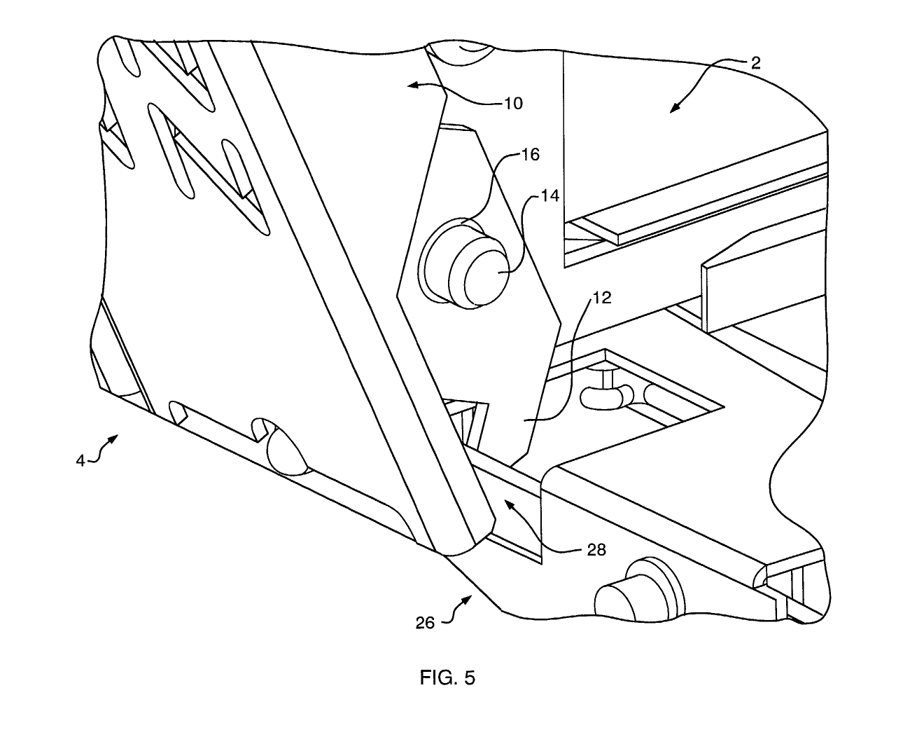

FIG. 5 shows an enlargement of the bottom portion of the panel 4 engaging the catch 28 on the tray 26. The rod or screw 14 which is attached to the sled module 2 and goes through the holes 16 in the panel 4 provides an axis around which the front panel 4 of the circuit sled module 2 can rotate. In FIG. 5, the panel 4 is shown rotated slightly in the counterclockwise direction from an upright position.

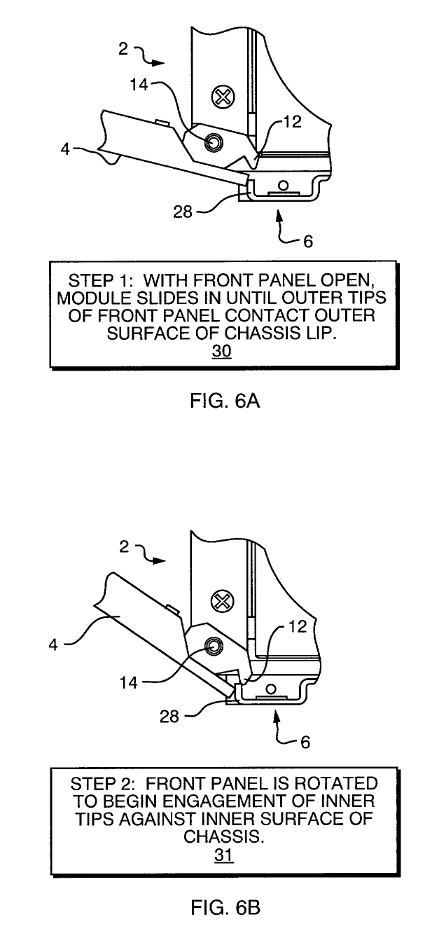

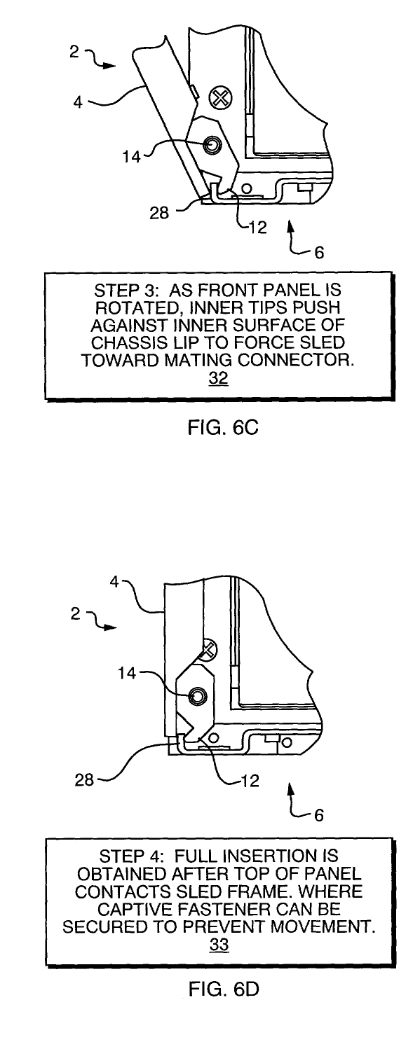

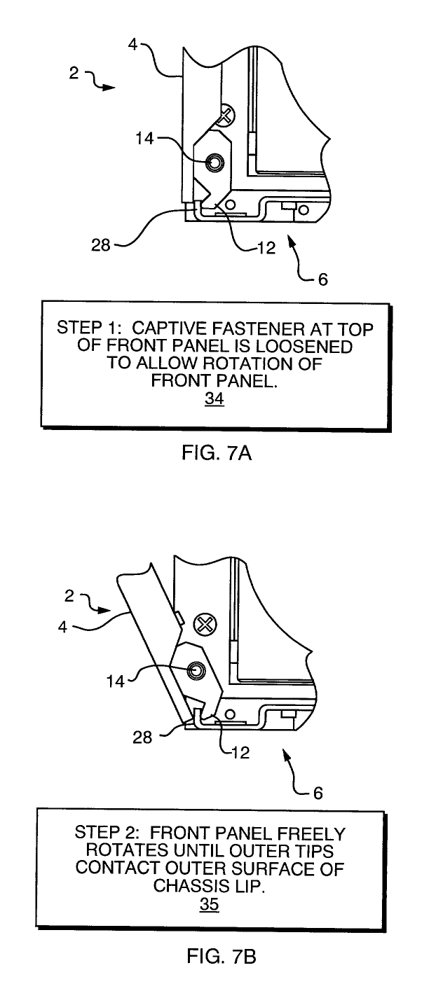

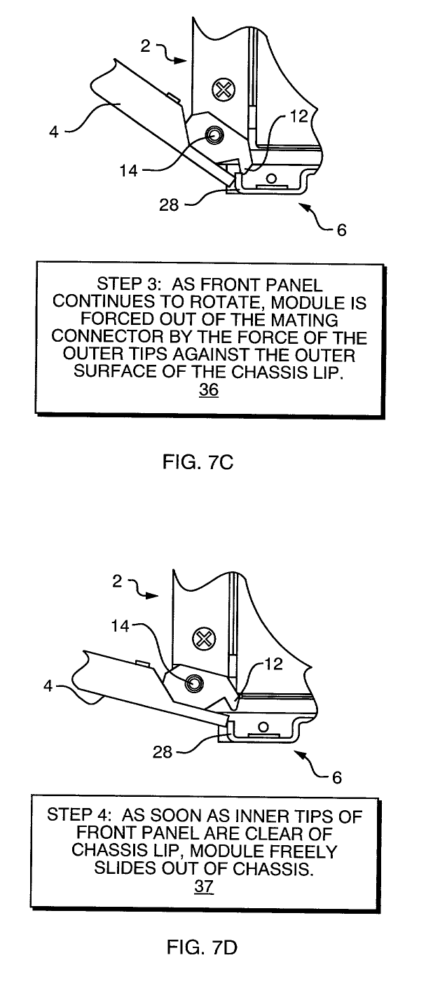

FIGS. 6A-6D show the sequence for inserting a circuit sled module with the steps following left to right. In these figures, as with FIGS. 7A-7D discussed later, the “outer tips” described in the steps 30-37 are the bottom portions of the panel 4, the “inner tips” are the hooks 12, and the “chassis lip” is the catch 28 on the tray 26. The mating connectors discussed in the figures and below are not shown, as they are on the end of the circuit sled module not shown in these figures. The mating connectors on the circuit sled module mate with corresponding connectors at the back of the tray. It often takes a considerable amount of force to insert or extract the sled modules as the mating connectors are engaging or disengaging. Thus it is desirable, to provide a front panel which serves as an insertion and extraction lever which applies the necessary leverage to aid in engaging or disengaging the mating connectors.

In FIGS. 6A-6D, as shown in step 1, 30, when a circuit sled module 2 is first inserted into a tray 26 the panel 4 is in the open position. In step 2, 31, the front panel 4 is rotated about the rod or screw 14 in the clockwise direction such that the hooks 12 begin to engage a catch 28 on the bottom of the tray 26 (chassis lip). In step 3, 32, as the panel 4 further rotates, the hooks 12 engage the inner surface of the catch 28 and this motion forces the circuit sled module toward a mating connector on the tray 26 (not shown) which engages the corresponding mating connector on the circuit sled module (also not shown). In step 4, 33, once the front panel 4 is fully vertical, the hooks 12 lock the bottom of the circuit sled module 2 in place while the screw or fastener 24 locks the top of the panel 4 in place thereby fully securing the sled module 2 in the tray 26 and preventing movement.

FIGS. 7A-7D show the circuit sled module extraction sequence with the steps following right to left. In step 1, 34, when it is necessary to remove the circuit sled module 2 from the tray 26, the screw or fastener 24 is loosened to allow the panel 4 to rotate counterclockwise about the axis formed by the rod or screw 14. In step 2, 35, the panel 4 is shown to rotate until the bottom portion (outer tips) of the panel 4 contacts the outer surface of the catch 28 (chassis lip) of the tray 26. In step 3, 36, as the front panel 4 continues to rotate, the circuit sled module is forced away from the mating connector (not shown) by the force of the bottom portion (outer tips) of the panel 4 pushing against the outer surface of the catch 28 (chassis lip) of the tray 26. In step 4, 37, once the hooks 12 have disengaged the catch 28 (chassis lip) on the bottom of the tray 26 the circuit sled module 2 freely slides out of the tray 26.

While this invention has been particularly shown and described with references to preferred embodiments thereof, it will be understood by those skilled in the art that various changes in form and details may be made therein without departing from the scope of the invention encompassed by the appended claims.

For example, the screw or fastener 24 can be replaced with any kind of clipping or locking mechanism including push button latches, key operated locks, or any other type of mechanism which can releasably lock the front panel in place when in a closed position. Similarly, rod 14 can be a screw or rivet or any other type of mechanism which allows the front panel 4 to rotate about an axis near one end of the front panel. Additionally, as described earlier, the hook 12 can be separate from the sidewalls 8 and 10 of the front panel, as shown in the figures herein, or it can be integrated directly with the side panels. Also, the panel 4 can be inverted such that the hooks 12 and holes 16 are near the top of the panel 4 and the screw or fastener 24 is near the bottom. In such an arrangement, the corresponding tray 26 and catch 28 for receiving the hooks, would also need to be inverted. Lastly, the grounding tabs 20 can be arranged in any fashion that electrically connects the front panel 4 to any other circuit sled module or the tray itself to provide a proper grounding.

What is claimed is:

1. A panel for a circuit sled module comprising:
a panel having a front, top, and a bottom, the panel being rotatably connected to the circuit sled module; and
at least one hook near the bottom of the panel engaging a catch of a tray when the panel is rotated into a closed position.

2. The panel of claim 1 further comprising a fastener releasably locking the panel to the circuit sled module.

3. The panel of claim 2 wherein the fastener is a screw attached to the panel.

4. The panel of claim 2 wherein the fastener is a clip.

5. The panel of claim 2 wherein the fastener is a key-operated lock.

6. The panel of claim 1 wherein the panel serves as a lever for extracting the circuit sled module from the tray when the panel is in an open position.

7. The panel of claim 1 further comprising at least one side wall having at least one hook extending from a portion of the side wall near the bottom of the panel.

8. The panel of claim 1 wherein the circuit sled module comprises a hard disk drive.

9. The panel of claim 1 further comprising vents in the front of the panel.

10. The panel of claim 1 further comprising electrically conductive grounding tabs electrically connecting the panel to an adjacent panel.

11. The panel of claim 1 wherein when the panel is rotated away from the circuit sled module the bottom of the panel engages an outer surface of the catch and provides a force which disengages mating connectors.

12. A panel for a circuit sled module comprising:
a panel having a front, top, and a bottom, the panel being rotatably connected to the circuit sled module; and
at least one hook near the bottom of the panel engaging a catch of a tray when the panel is in a closed position;
wherein the panel serves as a lever for extracting the circuit sled module from the tray when the panel is in an open position.

13. A panel for a circuit sled module comprising:
a panel having a front, top, bottom, and a left side wall and right side wall extending from the front;
holes in the side walls near the top of the panel, said holes receiving an axle connected to the circuit sled module, the panel rotating about an axis formed by the axle; and
at least one hook near the top of the panel engaging a catch of a tray when the panel is in a closed position.

14. A method for extracting a circuit sled module from a tray comprising:
providing a circuit sled module having a front panel comprising a front, top, and a bottom, the panel being rotatably connected to the circuit sled module;
rotating the front panel away from the circuit sled module until the bottom portion of the front panel engages a lip of a tray forcing the circuit sled module to be released from the tray; and
pulling on the front panel to extract the circuit sled module from the tray.

15. A method for inserting a circuit sled module into a tray comprising:
providing a circuit sled module having a front panel comprising a front, top, bottom, and at least one hook near the bottom of the panel engaging a catch of a tray when the panel is in a closed position, the panel being rotatably connected to the circuit sled module;
inserting the circuit sled module into the tray; and
rotating the front panel toward the closed position until the at least one hook engages the catch of the tray.
